(19) United States
(12) Patent Application Publication
(10) Pub. No.: US 2026/0068284 A1
(43) Pub. Date: Mar. 5, 2026

(54) POWER MODULE INTEGRATING SERIES- AND PARALLEL-CONNECTED SWITCH CHIPS

(71) Applicant: NUtech Ventures, Lincoln, NE (US)

(72) Inventors: Jun Wang, Lincoln, NE (US); Ekaterina Muravleva, Lincoln, NE (US); Youssef Abotaleb, Lincoln, NE (US)

(21) Appl. No.: 19/314,175

(22) Filed: Aug. 29, 2025

Related U.S. Application Data
(60) Provisional application No. 63/688,475, filed on Aug. 29, 2024.

(51) Int. Cl. H10D 80/20; H01L 23/00; H01L 23/367; H01L 23/535; H01L 23/64; H01L 25/00; H01L 25/07; H10D 86/00; H10D 86/01

(52) U.S. Cl. CPC H10D 80/251; H10D 86/01; H10D 86/201

(57) ABSTRACT

The present disclosure provides a semiconductor power module. The semiconductor power module includes a first substrate, a second substrate, and a plurality of switch bars stacked and laterally positioned between the first substrate and the second substrate. Each switch bar includes a plurality of dies disposed in parallel, each die of the plurality of dies comprising a switch device with a source, a drain, and a gate, a gate driver printed circuit board (PCB) connected to the gates of the switch devices in the plurality of dies, and interconnects configured to connect the sources and drains of the switch devices in the plurality of dies. The switch devices of the same switch bar are electrically connected in parallel and respective switch devices of different switch bars are electrically connected in series.

### CROSS-REFERENCE TO RELATED APPLICATIONS

This application claims the benefit of U.S. Provisional Application No. 63/688,475, filed Aug. 29, 2024, the entire contents of which is incorporated herein by reference.

### BACKGROUND

The rapid growth in electricity demand driven by artificial intelligence (AI) data centers and electric vehicle (EV) fast chargers is straining the existing grid distribution infrastructure. To address this, medium-voltage alternating current (MVAC) to low-voltage direct current (LVDC) power factor correction (PFC) rectifiers with higher power, efficiency, and density, as well as bidirectional power flow capabilities, are urgently needed. However, a critical challenge lies in the lack of higher-voltage (>10 kilovolts (kV)), higher-current (>1 kiloampere (kA)) silicon carbide (SiC) power semiconductor modules, which are essential for enabling simpler and more efficient grid converter topologies. SiC metal-oxide-semiconductor field-effect transistor (MOSFET) or junction field-effect transistor (JFET) dies, being small with limited voltage and current ratings but very fast switching speed, require module designs that effectively address parallel-series die connections, parasitics, partial discharge (PD) concerns, and thermal management for practical medium-voltage (MV) grid applications.

Existing SiC modules rated above 3.3 kV mainly adopt half-bridge configurations with multiple parallel dies per switch position, where the power-loop inductance (Ls) is a critical performance metric. These 3.3 kV SiC modules typically offer current ratings ranging from 200 A-1000 A, primarily targeting traction inverter applications. These SiC modules exhibit 10 nH-35 nH Ls when using external decoupling capacitors, while incorporating MV multi-layer ceramic capacitor (MLCC) decoupling capacitors directly within the module packaging can reduce Ls to as low as 6.9 nH. SiC modules rated higher than 3.3 kV, 1 kA are presently unavailable. Existing 6 kV-7.2 kV SiC modules are rated below 400 A with Ls exceeding 23 nH when using external decoupling capacitors. By confining the power loop between two substrates, Ls can be reduced to 2.6 nH; this technique is also seen in 1.2 kV SiC module designs. Current 10 kV SiC modules are rated below 240A with a 16.0 nH Ls when using external decoupling capacitors. Designs with internal MLCC decoupling capacitors have achieved inductance values of 4.4 nH or 5.6 nH. On the other hand, SiC modules featuring in-package series die configurations remain scarce. Certain technology packaged six 1.2 kV series-connected dies with respective RC snubbers to build a 6.5 kV single-switch-position module (not half bridge). A study compared metal spacer versus bond wire connections and evaluates different layouts, attaining a minimum Ls of 24.6 nH. Certain technology used two series-connected 1.2 kV dies per switch position (a total of four dies) to make a 2.4 kV half-bridge module, obtaining 5.8 nH with an internal MLCC capacitor. The aforementioned research efforts highlight two critical limitations in existing designs: (1) Achieving Ls<10 nH without integrating internal decoupling capacitors seems impractical. However, embedding MLCC capacitors within the high-temperature module environment introduces reliability concerns, especially the short-circuit ruggedness concern due to their susceptibility to mechanical stress. (2) Configuring SiC dies in both parallel and series connections requires an extensive substrate area, making it very challenging to accommodate both configurations simultaneously for high power MV grid applications.

Power modules with isolated substrates have junctions at the interface among the ceramic layer, copper plate, and silicone gel or epoxy, commonly referred to as triple points. The high voltage across copper plates creates a strong, distorted electric field (E-field) at the triple points, increasing the occurrence of PD events. These events accelerate electrical treeing, especially under square-wave excitation, leading to premature power module breakdown. PD mitigation strategies are categorized into two paths: optimizing substrate geometry and employing advanced dielectric/semiconductor materials. The former include stacked substrates, ceramic geometry modifications, field plates, and electret structures. Among these, stacked substrates with dc midpoint (dc-mid) referencing, which create bipolar, symmetrical voltage stresses, offer the simplest solution without significantly complicating the manufacturing process. However, this design necessitates embedding decoupling capacitors within the package, raising the same short-circuit ruggedness concern of the MLCC capacitors as previously noted. In general, maintaining the E-field below 30 kV/mm at a distance of 15 μm from the worst-case triple point is preferred. For modules with in-package series-connected dies, certain technology optimized the dimensions of the substrate copper plate and copper spacer, specifically for a single-sided cooling structure.

Dual-sided cooling designs for EV power modules rated up to 1.2 kV with in-package parallel dies have been studied. These designs sandwich all dies between two substrates, employing two main approaches to enable heat transfer through the die's front side: direct bonding to a top substrate or through metal spacers. In either approach, the dies for both half-bridge switch positions can be entirely bonded to the bottom substrate. Alternatively, the dies of one switch position can be mounted on the bottom substrate, while those of the other switch position are placed on the top substrate to minimize Ls. The variations in thermal resistance with dual-sided cooling primarily depend on the die area (very different between Si IGBTs and SiC MOSFETs) and metallization, as well as the materials and geometries of the direct bonded copper (DBC)/active metal brazed (AMB)/optimized direct bonded copper (ODBC) substrates, metal spacers, Cu/AlSiC baseplates (with or without cooling channels), and all bonding mediums. The junction-to-case thermal resistance per die R_{th,j-c,die} for low-voltage dies is ranged in 0.018 K/W-0.4 K/W. For modules utilizing metal spacers, a method for further reducing thermal resistance involves filling the non-conductive gaps with low-temperature co-fired ceramic (LTCC) interposers (some loaded with graphene or pyrolytic graphite sheets), thereby enhancing thermal routing and mechanical support between the two substrates. From the thermal perspective, these designs also apply to >3.3 kV parallel-die modules if PD is well addressed. Nevertheless, for high-power grid-oriented modules with in-package parallel-series dies, the limited substrate area remains a challenge.

Scalable packaging solutions for accommodating substantial in-package parallel-series SiC dies, targeting MV grid distribution, remain unexplored. Existing package designs for Ls minimization, PD mitigation, and dual-sided cooling render valuable design guidance but fall short of achieving optimal overall performance.

### SUMMARY

In an exemplary embodiment, a semiconductor power module is provided. The semiconductor power module includes a first substrate, a second substrate, and a plurality of switch bars stacked and laterally positioned between the first substrate and the second substrate. Each switch bar includes a plurality of dies disposed in parallel, each die of the plurality of dies comprising a switch device with a source, a drain, and a gate, a gate driver printed circuit board (PCB) connected to the gates of the switch devices in the plurality of dies, and interconnects configured to connect the sources and drains of the switch devices in the plurality of dies. The switch devices of the same switch bar are electrically connected in parallel and respective switch devices of different switch bars are electrically connected in series.

According to an embodiment of the semiconductor power module, the plurality of dies in the plurality of switch bars are positioned on a first surface of the respective switch bars, and the first surface of each respective switch bar is perpendicular to a surface of the first substrate and a surface of the second substrate.

According to an embodiment of the semiconductor power module, the gate driver PCB is connected to the first surface of the respective switch bar.

According to an embodiment of the semiconductor power module, a second surface of each switch bar of the plurality of switch bars comprises a plurality of pyramid extrusions corresponding to the plurality of dies on the respective switch bar. The second surface of the respective switch bar faces opposite to the first surface of the respective switch bar.

According to an embodiment of the semiconductor power module, the semiconductor power module further includes a heatsink connected to the first substrate, and one or more third substrates connected to the second substrate.

According to an embodiment of the semiconductor power module, the one or more third substrates correspond to separate heatsink voltage potentials.

According to an embodiment of the semiconductor power module, the semiconductor power module further includes a plurality of decoupling capacitors. The plurality of decoupling capacitors is connected to the second substrate and positioned between adjacent third substrates of the one or more third substrates.

According to an embodiment of the semiconductor power module, the first and second substrates are active metal brazed substrates.

According to an embodiment of the semiconductor power module, the plurality of switch devices are metal-oxide-semiconductor field-effect transistors (MOSFETs) or junction field-effect transistors (JFETs).

According to an embodiment of the semiconductor power module, the each switch bar of the plurality of switch bars comprises a copper bar.

In a further exemplary embodiment, a semiconductor power module is provided. The semiconductor power module includes a plurality of submodules and a heatsink connected to first substrates of the plurality of submodules. Each submodule of the plurality of submodules includes a first substrate, a second substrate, and a plurality of switch bars stacked and laterally positioned between the first substrate and the second substrate. Each switch bar includes a plurality of dies disposed in parallel, each die of the plurality of dies comprising a switch device with a source, a drain, and a gate, a gate driver printed circuit board (PCB) connected to the gates of the switch devices in the plurality of dies, and interconnects configured to connect the sources and drains of the switch devices in the plurality of dies. The switch devices of the same switch bar are electrically connected in parallel and respective switch devices of different switch bars are electrically connected in series.

According to an embodiment of the semiconductor power module, the plurality of submodules is oriented in different directions.

According to an embodiment of the semiconductor power module, the plurality of dies in the plurality of switch bars are positioned on a first surface of the respective switch bars, and the first surface of each respective switch bar is perpendicular to a surface of the first substrate and a surface of the second substrate.

According to an embodiment of the semiconductor power module, the gate driver PCB is connected to the first surface of the respective switch bar.

According to an embodiment of the semiconductor power module, a second surface of each switch bar of the plurality of switch bars comprises a plurality of pyramid extrusions corresponding to the plurality of dies on the respective switch bar. The second surface of the respective switch bar faces opposite to the first surface of the respective switch bar.

According to an embodiment of the semiconductor power module, the semiconductor power module further includes one or more third substrates connected to the second substrates of the plurality of submodules.

According to an embodiment of the semiconductor power module, the one or more third substrates correspond to separate heatsink voltage potentials.

According to an embodiment of the semiconductor power module, the semiconductor power module further includes a plurality of decoupling capacitors. The plurality of decoupling capacitors is connected to the second substrates of the plurality of submodules and positioned between adjacent third substrates of the one or more third substrates.

According to an embodiment of the semiconductor power module, the plurality of switch devices are metal-oxide-semiconductor field-effect transistors (MOSFETs) or junction field-effect transistors (JFETs).

In yet a further exemplary embodiment, a method is provided for packaging a semiconductor power module. The method includes fabricating a plurality of switch bars, wherein each switch bar of the plurality of switch bars, stacking the plurality of switch bars, and laterally positioning the stacked switch bars between a first substrate and a second substrate. Each switch bar of the plurality of switch bars includes a plurality of dies disposed in parallel, each die of the plurality of dies comprising a switch device with a source, a drain, and a gate, a gate driver printed circuit board (PCB) connected to the gates of the switch devices in the plurality of dies, and interconnects configured to connect the sources and drains of the switch devices in the plurality of dies.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

The present systems and methods for power module packaging are described in detail below with reference to the attached drawing figures, wherein:

FIG. 1A is a circuit topology of a half-bridge module with two series-connected dies at each switch position, in accordance with one or more embodiments of the present disclosure.

FIG. 1B is a schematic illustrating a half-bridge module corresponding to the circuit topology of FIG. 1A, in accordance with one or more embodiments of the present disclosure.

FIGS. 2A-2E illustrate a process for fabricating a module, in accordance with one or more embodiments of the present disclosure.

FIG. 3A illustrates an example half-bridge module, in accordance with one or more embodiments of the present disclosure.

FIG. 3B is a top perspective view of the module, in accordance with one or more embodiments of the present disclosure.

FIGS. 3C and 3D illustrate example electrical interfaces of the module, in accordance with one or more embodiments of the present disclosure.

FIG. 3B is a top perspective view of the module, in accordance with one or more embodiments of the present disclosure.

FIG. 4 illustrates a module circuit topology of the half-bridge module and example voltage potentials, in accordance with one or more embodiments of the present disclosure.

FIG. 5 illustrates a cross-section view of the half-bridge module, in accordance with one or more embodiments of the present disclosure.

FIG. 6 shows E-field results, in accordance with one or more embodiments of the present disclosure.

FIG. 7 illustrates thermal simulations, in accordance with one or more embodiments of the present disclosure.

FIG. 8 illustrates thermal simulation results, in accordance with one or more embodiments of the present disclosure.

### DETAILED DESCRIPTION

The present disclosure introduces a dual-orthogonal-cooling (DOC) packaging concept that positions the dies perpendicularly to the substrate using a switch bar structure. In certain aspects, the switch bars are designed to conduct high currents horizontally; confine power loops within the ceramic layer of the top substrate and external decoupling capacitors; segment voltage stresses to limit maximum electric field (E-field) and the rate at which voltage changes over time (e.g., denoted as dv/dt); and spread heat to enable DOC through dual-sided heat dissipation. This packaging design advantageously reduces the package footprint and features high scalability to accommodate various power ratings and topologies.

In certain embodiments, lateral-scaling orthogonal-cooling packages are fabricated based on the DOC packaging concept, providing a novel high-voltage, high-current power module architecture that employs series and parallel connections of multiple lower-voltage SiC dies.

In certain embodiments, dies are sintered to a copper bar aka “copper switch bar.” The switch bars are stacked—each one on top of the other—and sintered. The sintered stack is then placed and bonded horizontally on the bottom substrate, where a second substrate is placed on top. As a result, the dies within the module are perpendicular to the top substrate and the bottom substrate.

The technology implementing the DOC packaging concept advantageously improves heat management in power modules. Orthogonal cooling is achieved by packing dies in the manner described herein. This technology may replace conventional packaging of power modules.

A common packaging technology includes wire-bond modules, where power semiconductor dies are soldered on an insulated-metal substrate, interconnected with aluminum wires, and encapsulated inside a silicone gel. Modules made by these conventional packaging technologies have low power density limited by a maximum heat dissipation of about 100 to 200 W/cm². These conventional packaged modules also generally have high parasitic inductances and poor reliability from wire-bond lift-off, die-attach cracking, and substrate delamination.

Furthermore, conventional high-frequency silicon carbide (SiC) power modules with isolated substrates typically bond the SiC dies directly onto the substrates. Although effective for parallel die configurations and simple package topologies, this design becomes limiting for high-voltage, high-current modules that require parallel-series die connections in the package and complex topologies.

The DOC packaging concept disclosed herein addresses these limitations.

In certain embodiments, by sintering the SiC die to the copper bars and placing the copper bars on their side between the substrate, the SiC MOSFET dies are perpendicular to the substrate. This results in the current flow in one direction and heat dissipation perpendicular to the current flow. Heat is dissipated more efficiently through the copper bar and to the heat sink.

In certain embodiments, a semiconductor power module package may include sintered metal switch bars stacked and laterally positioned between a first substrate and a second substrate. Each metal switch bar includes sintered dies in parallel, soldered gate driver PCB, and wire bonded gate and source (e.g., Kelvin source or power source).

The proposed DOC packaging concept has been validated through finite element analysis (FEA) simulations, demonstrating reduced power-loop inductance, mitigated E-field near triple points, and enhanced thermal performance.

More illustrative information will now be set forth regarding various optional configurations and features with which the foregoing DOC packaging concept may be implemented, per the desires of the user. It should be strongly noted that the following information is set forth for illustrative purposes and should not be construed as limiting in any manner. Any of the following features may be optionally incorporated with or without the exclusion of other features described.

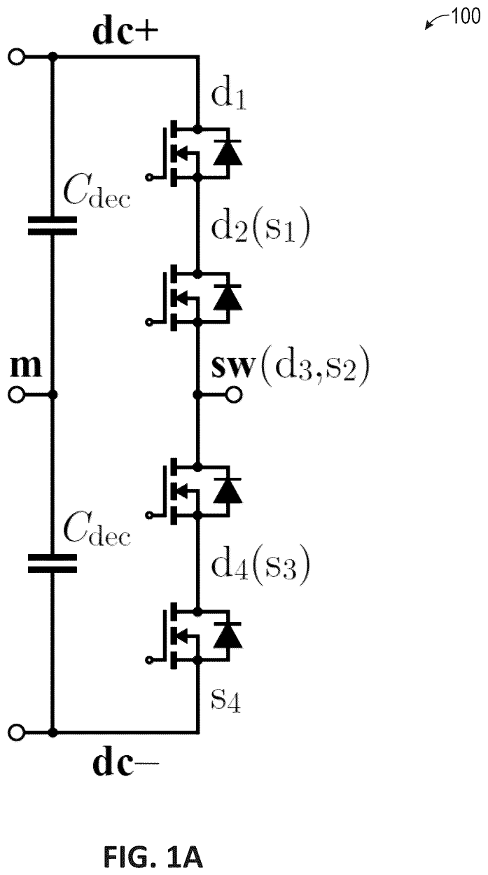

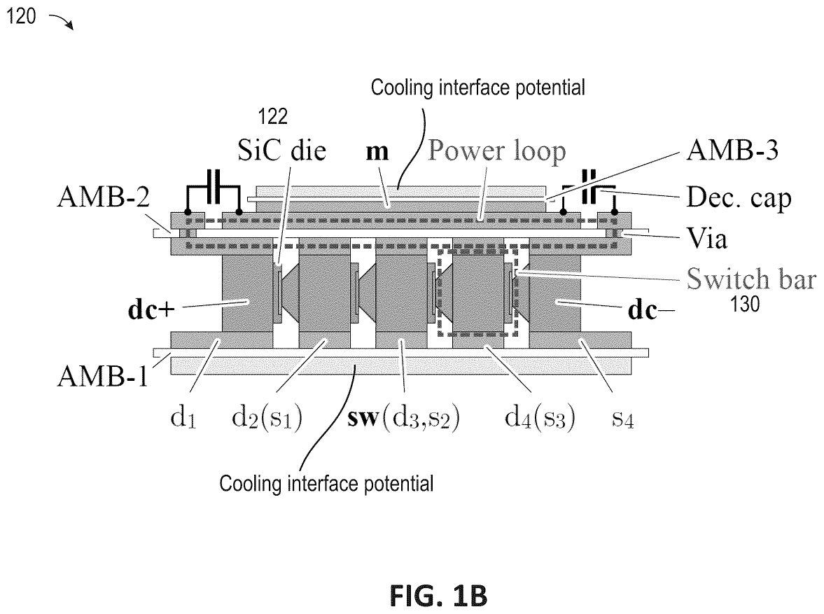

FIG. 1A is a circuit topology 100 of a half-bridge module with two series-connected dies at each switch position, in accordance with one or more embodiments of the present disclosure. In the illustrated example, the half-bridge module includes four MOSFET devices, where “d” designates a drain terminal, “s” designates a source terminal of the corresponding MOSFET device, “dc+” and “dc−” denote positive and negative dc bus terminals, respectively, “m” designates a terminal corresponding to a dc-mid potential, and “sw” designates a switch node terminal.

FIG. 1B is a schematic illustrating a half-bridge module 120 corresponding to the circuit topology 100 of FIG. 1A, in accordance with one or more embodiments of the present disclosure. In the illustrated example, each MOSFET device is fabricated on a silicon carbide (SiC) die 122.

As shown in FIG. 1B, a SiC die 122 may be integrated with a corresponding switch bar 130. The switch bar is an electrically conductive bar, which may be formed from a conductive metal such as copper. A plurality of switch bars 130, integrated with the corresponding SiC dies 122, are stacked such that in the example shown in FIG. 1B, each of the four SiC dies 122 is disposed between adjacent switch bars 130. Hereinafter, the term “switch bar” may also refer to a configuration in which the switch bar 130 is integrated with the corresponding SiC die(s) 122. The stack of the switch bars 130 are disposed between two active metal brazed substrates, denoted as AMB-1 and AMB-2 substrates, respectively. In certain embodiments, the AMB-1 and AMB-2 substrates are patterned with interconnects (e.g., metal traces, bond wires, vias, etc.) and/or bonding pads. This configuration allows the MOSFET devices on the corresponding SiC dies 122 to be connected in accordance with the circuit topology 100 shown in FIG. 1A.

The two outermost switch bars 130 of the stack may serve as the source terminals “dc+” and “dc−,” respectively. The “m” and “sw” terminals may be positioned on the AMB-1 and AMB-2 substrates, respectively. Decoupling capacitors (denoted as “Dec. cap” or “C_{dec}”) are connected to the AMB-2 substrate. A third AMB substrate (AMB-3) is bonded onto the AMB-2. In certain embodiments, suitable cooling components of systems may be connected to the AMB-1 and/or AMB-3 substrates, as indicated by the cooling interface potential blocks.

The half-bridge module 120 shown in FIG. 1B illustrates an example implementation of a scalable DOC packaging concept, which can achieve a balanced performance across scalability, footprint, parasitics, E-field, and thermal management.

A noted element of the DOC package is the switch bar structure. In certain embodiments, a switch bar includes a slim copper bar that carries multiple parallel dies arranged in a line.

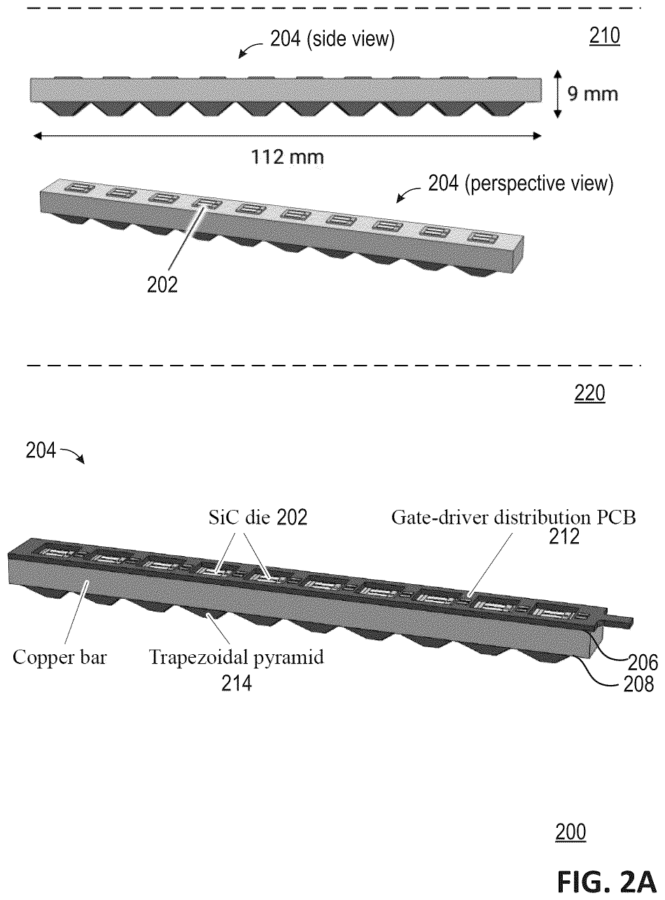

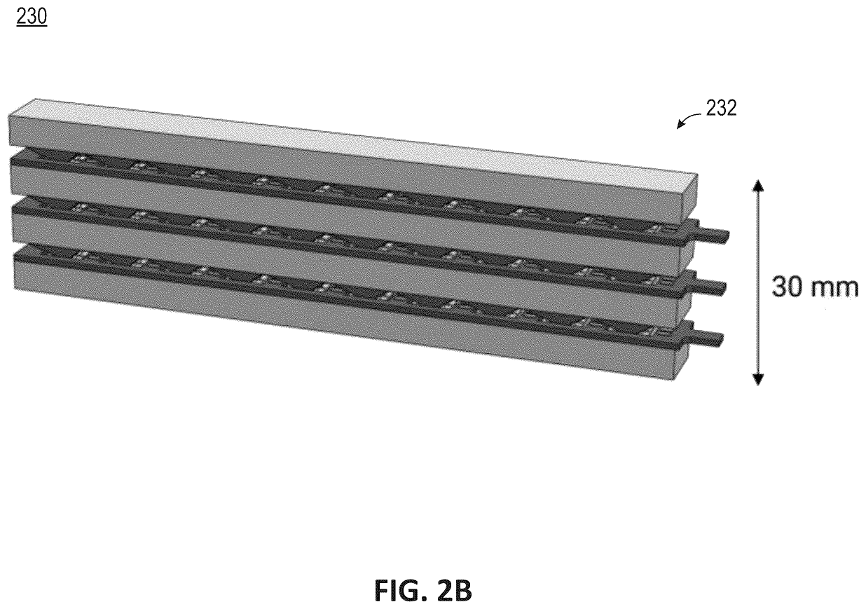

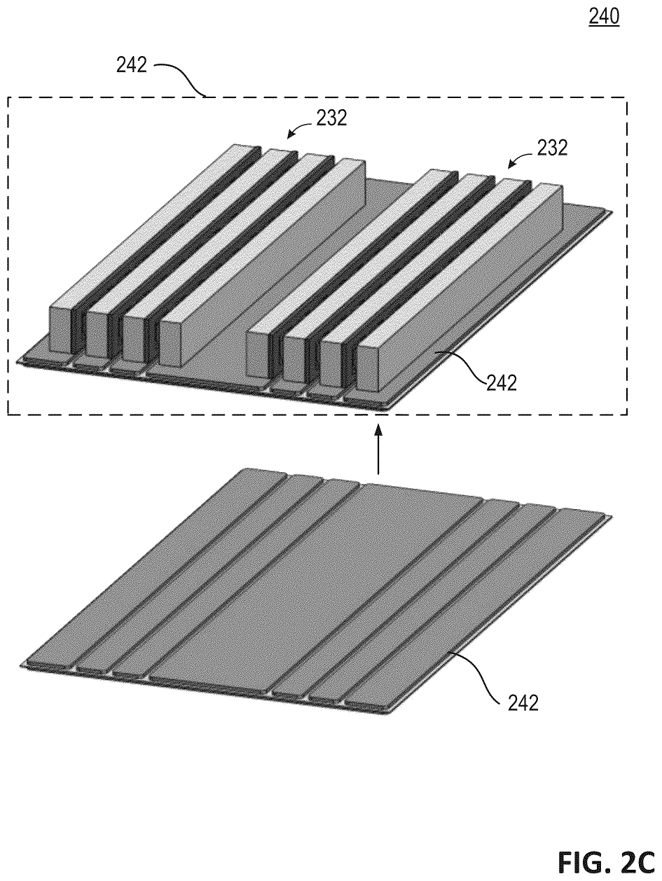

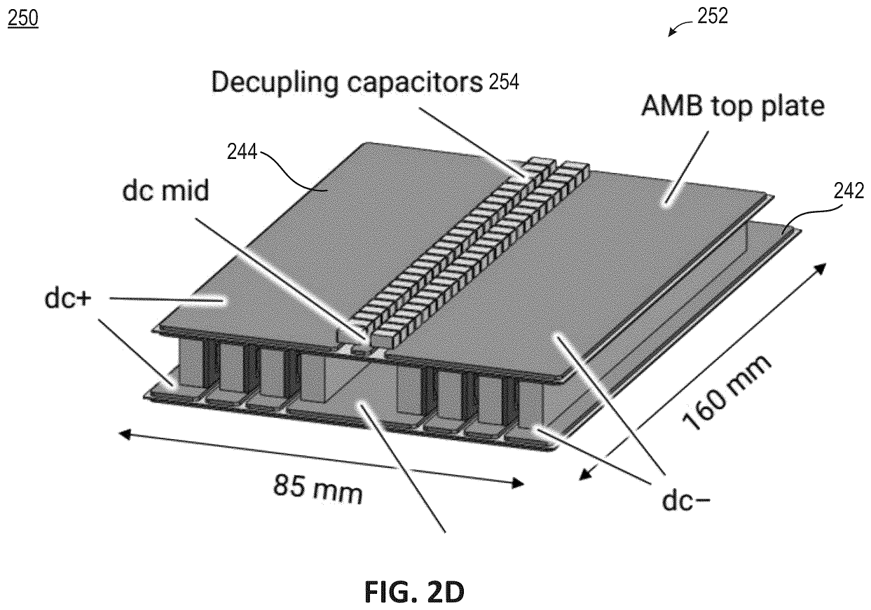

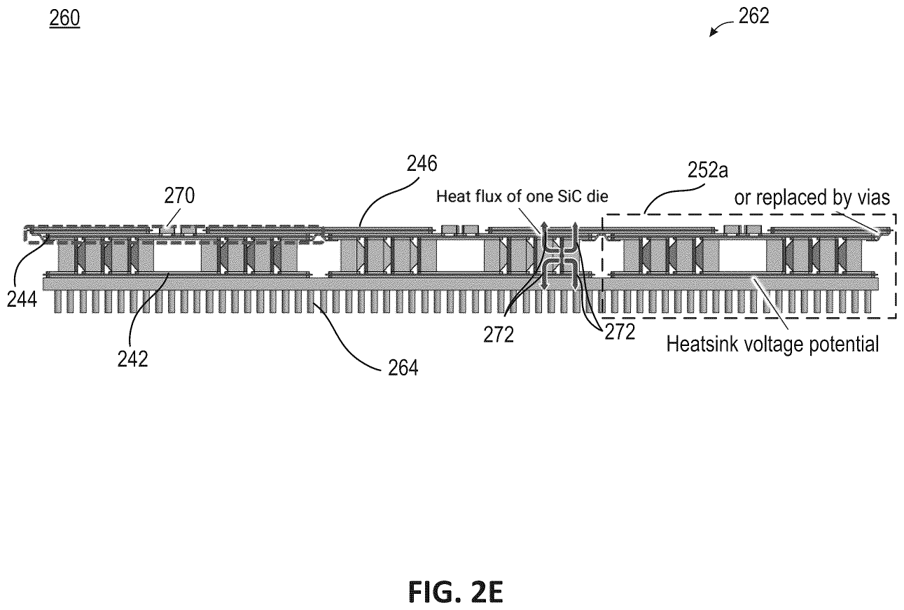

FIGS. 2A-2C illustrate a process 200 for fabricating a module 262, in accordance with one or more embodiments of the present disclosure. Process 200 may be performed alone or in combination with other processes in the present disclosure. It will be recognized that process 200 may be performed in any suitable environment and in any suitable order except where otherwise apparent. Alternative steps may be performed instead of or in addition to those shown, and some steps may be omitted entirely.

In certain embodiments, process 200 is performed to fabricate a half-bridge module 120 as shown in FIG. 1B.

At step 210, a plurality of dies 202 are connected to a copper bar to form a switch bar 204. For example, the dies 202 may be sintered to the copper bar 204. However, other suitable bonding techniques may alternatively be employed. In at least one embodiment, the dies 202 are 1.7 kV SiC MOSFET dies. This configuration may provide a switch bar rated at 1.7 kV and 500 A, with dimensions of 112 millimeters (mm) in length and 9 mm in thickness.

At step 220, a gate-driver distribution PCB 212 can be mounted on the same surface 206 as the dies 202. In certain embodiments, the gate-driver distribution PCB 212 may be connected to the gate and source pads via bond wires. However, other suitable electrical connections may alternatively be formed. In certain embodiments, additional and/or alternative components may be mounted on the surface 206 as the dies 202, including Rogowski coils.

The opposite side of each die (e.g., in surface 208 of the switch bar 204) includes trapezoidal pyramid extrusions 214, enabling the horizontal stacking of switch bars 204 to create series die connections.

At step 230, the switch bars are arranged in a stack to form a switch bar assembly 232. For example, the switch bars 204 are used to interconnect three devices in series to form a switch position, as in a phase-leg configuration within the stack. For example, the switch bar assembly 232 serves as one phase-leg. In certain embodiments, the stacking of the switch bars 204 may be formed simultaneously in a single sintering operation, or alternatively, the switch bars 204 may be stacked sequentially, one after another. In the illustrated example, the switch bar assembly 232 may have a thickness of 30 mm.

At step 240, two switch bar assemblies 232 are mounted to an AMB substrate 242. For example, the AMB substrate may include a 0.8 mm-thick copper layer, which provides an effective skin depth of approximately 0.46 mm at an operating frequency of 20 kHz. The switch bar assemblies 232 may be sintered to the AMB substrate 242 for the required isolation to cooling liquid.

At step 250, an AMB substrate 244 may be connected (e.g., sintered) to the top side of the switch bar assemblies 232. The sides 216 and 218 of the switch bars 204 may act as cooling interfaces, for example, bonded to the AMB substrates 242 and 244 at the bottom and top, respectively. In this configuration, all dies 202 are oriented perpendicularly to the AMB substrates 242 and 244. In certain embodiments, one or more decoupling capacitors 254 may be mounted to the AMB substrate 244, for example, by soldering or other suitable bonding techniques.

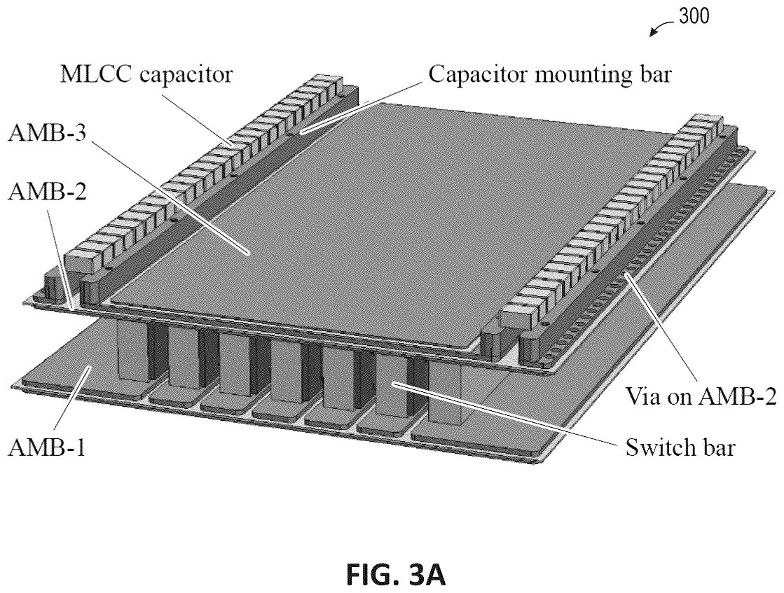

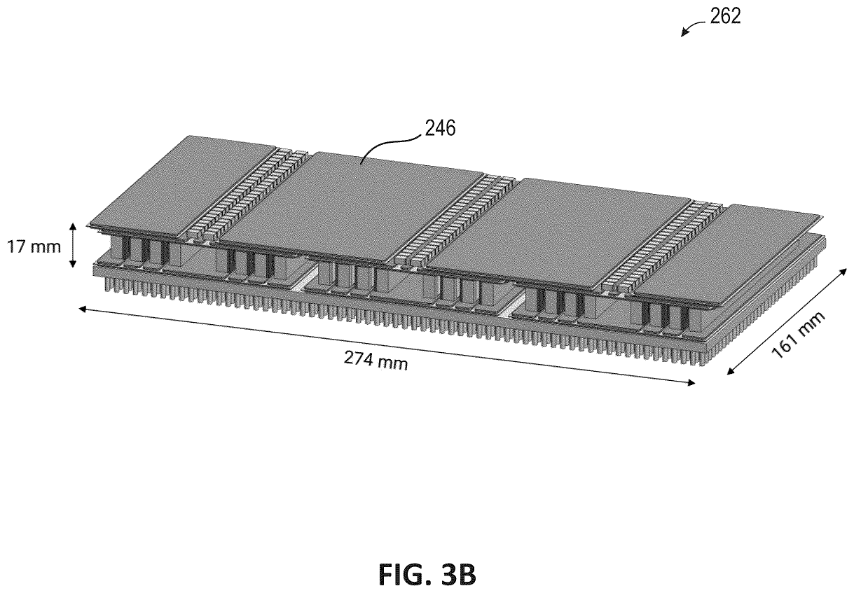

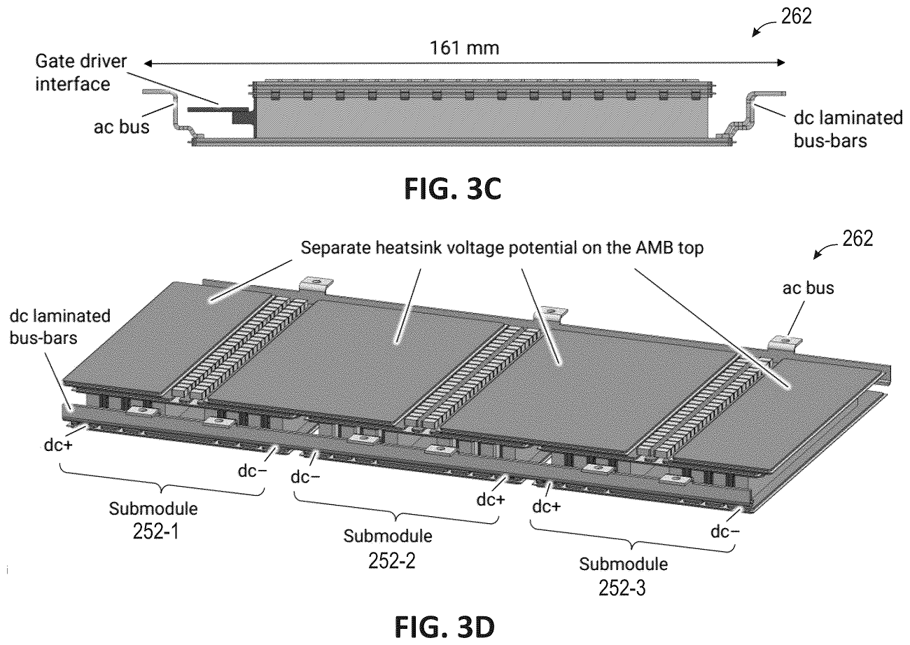

In certain embodiments, the AMB substrate 244 is designed with connectivity between the bottom and top copper plates at the left and right edges, e.g., by means of solder-filled vias. For example, the top layer of the AMB substrate 244 may include three separate copper plates. The left and right top copper plates may be connected to dc+ and dc−terminals, respectively, The top middle copper plate on the AMB substrate 244 is designed to connect to the dc−mid potential (e.g., the “m” terminal), facilitating the external placement of decoupling capacitors (e.g., multilayer ceramic capacitors (MLCCs)) between the top middle copper plate and the top left/right copper plate. Furthermore, the AMB substrate 242 may be patterned with a plurality of separate copper plates. An exemplary connection for the dc+, dc−, and alternating current (ac) terminals is illustrated in FIG. 2D (as well as in FIG. 3D).

Steps 210 through 250 may be performed to fabricate a submodule 252 rated at 5.1 kV and 500 A. For example, a DOC half-bridge module with a total of 60 dies may be formed, with each switch position consisting of 10-parallel-3-series 1.7 kV, 50 A SiC dies. The AMB substrates 242 and/or 244 may have dimensions of 85 mm by 160 mm.

At step 260, a module 262 is formed by mounting a plurality of submodules 252 (e.g., as indicated by dashed box 252a) onto a heatsink 264. For example, three submodule 252 are soldered onto a pin-fin heatsink. In the illustrated example, the submodules 252 positioned on the left and right are oriented in a different direction compared to the middle submodule 252. For example, the pyramid extrusions are oriented differently. It will be noted that the plurality of submodules 252 may be oriented arbitrarily, subject to various design requirements. In certain embodiments, the three submodule 252 may correspond to three leg phases in the module 262.

In certain embodiments, for galvanic isolation, a third substrate (e.g., an AMB substrate 246), is bonded onto the AMB substrate 244. Since the AMB substrate 246 does not carry high current, it can be designed with minimal copper and ceramic thicknesses, enhancing top-side heat dissipation. Notably, the bottom copper plate of the AMB substrate 242 and the top copper plate of the AMB substrate 246, both at the cooling interface potential, are connected to the dc-mid potential through high impedance for E-field management and minimal leakage current.

As indicated in dashed box 270, a power loop of a submodule exhibits a total inductance, e.g., of approximately 4.2 nanohenries (nH); this total inductance corresponds to three parallel power loops, e.g., each having an individual inductance of about 1.4 nH. Arrows 272 indicate the directions of heat flux for a single SiC die.

Heatsink voltage potential refers to the electrical potential (voltage) of a heatsink relative to a reference point (e.g., circuit ground). In certain embodiments, the bottom of the first AMB substrate 242 is bonded directly to the heatsink 264 without an isolation plate, and that copper layer (e.g., the top copper plate of the first AMB substrate 242) is tied to the drain of a MOSFET, then the heatsink voltage potential is MOSFET drain potential.

In certain embodiments, AMB interconnection may be implemented through lead frames, and vias may be formed in the AMB substrates. As shown in FIG. 2E, the AMB substrate 246 is mounted on the top to provide isolated dual-side cooling.

FIG. 3A illustrates an example half-bridge module 300, in accordance with one or more embodiments of the present disclosure. As shown in FIG. 3A, the bottom and top sides of a switch bar assembly are mounted to a first AMB substrate (AMB-1) and a second AMB substrate (AMB-2). A third AMB substrate (AMB-3) is bonded onto the AMB-2. The half-bridge module 300 provides an alternative submodule design to the submodule 252 shown in FIG. 2D. In certain embodiments, the outer housing may include three submodules 300 connected in parallel to form a single phase leg with a triple current rating, or arranged as three separate phase legs.

FIG. 3B is a top perspective view of the module 262, in accordance with one or more embodiments of the present disclosure. The module 262 may have dimensions of 274 mm by 161 mm by 17 mm.

FIGS. 3C and 3D illustrate example electrical interfaces of the module 262, in accordance with one or more embodiments of the present disclosure. The module 262 includes submodules 252-1, 252-2, and 252-3. The ac bus and the dc bus-bars may be extended from opposite sides of the first AMB substrate 242. A plurality of third AMB substrates 246 correspond to separate heatsink voltage potentials.

The dc+ and dc− terminals are interleaved along an edge of the module 262. This arrangement reduces voltage stresses.

The DOC package disclosed herein provides several advantages. (1) High scalability: Extending the length of the switch bar to accommodate more dies increases the module's current rating, while laterally stacking more bars enhances the voltage rating. (2) Compact footprint: The switch bars are tightly integrated, minimizing the overall footprint regardless of die dimensions and spacing. (3) Reduced parasitics: The power loop is confined within the AMB-2 (e.g., the second AMB substrate 244) ceramic layer, with minimal gaps between the switch bars, achieving power-loop inductance below 10 nH even if external decoupling capacitors are used. (4) External decoupling capacitors: The design lowers the ambient temperature around the MLCC capacitors, mitigates short-circuit ruggedness concerns, and allows for easy replacement of damaged capacitors without replacing the module. (5) Reduced triple-point E-field: The internal E-field is effectively graded by segmenting the switching potentials, preventing the close proximity of copper layers with high voltage differentials. Additionally, the use of the dc-mid (e.g., the “m” terminal) as a reference potential halves the maximum voltage difference by creating bipolar, symmetrical voltage stresses. (6) Dual orthogonal cooling: Heat flux is generated horizontally on both sides of the dies and dissipates vertically through the two substrates, forming a DOC mechanism. While achieving the lowest per-die junction-to-case thermal resistance may be challenging compared to existing dual-sided cooling modules, a decent thermal resistance is attainable. This trade-off is acceptable given the compact and highly integrated design.

In certain embodiments, the half-bridge module shown in FIG. 3A is evaluated via simulations, such as finite element analysis (FEA) verification.

In the illustrated example, four capacitor mounting bars are bonded onto AMB-2, facilitating the assembly of MLCC decoupling capacitors and separating them from the module package. The MLCC capacitor assemblies are intended to be potted for enhanced stability and insulation.

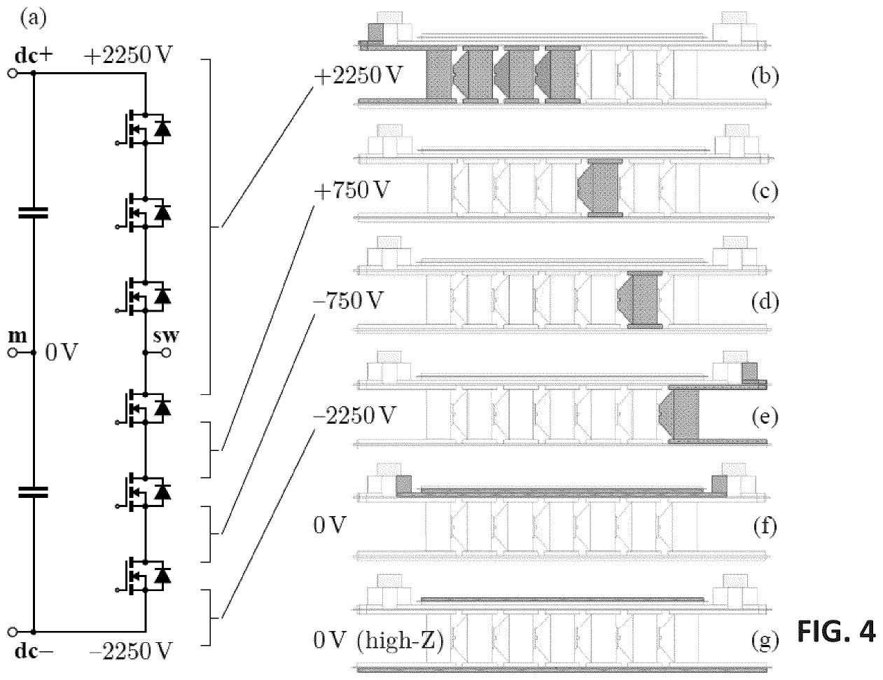

FIG. 4 illustrates a module circuit topology of the half-bridge module in (a) and example voltage potentials in (b)-(g), in accordance with one or more embodiments of the present disclosure. Conductive parts are at the potentials of (b) +2250V, (c) +750V, (d) −750V, (e) −2250V, (f) dc-mid 0V, and (g) cooling interfaces 0V (connected to dc-mid through high impedance). With a 4.5 kV dc bus, when the top switch position is turned on, the voltage potentials of all conductive parts are illustrated in FIG. 4. A mirrored voltage potential distribution will occur when the bottom switch position is turned on.

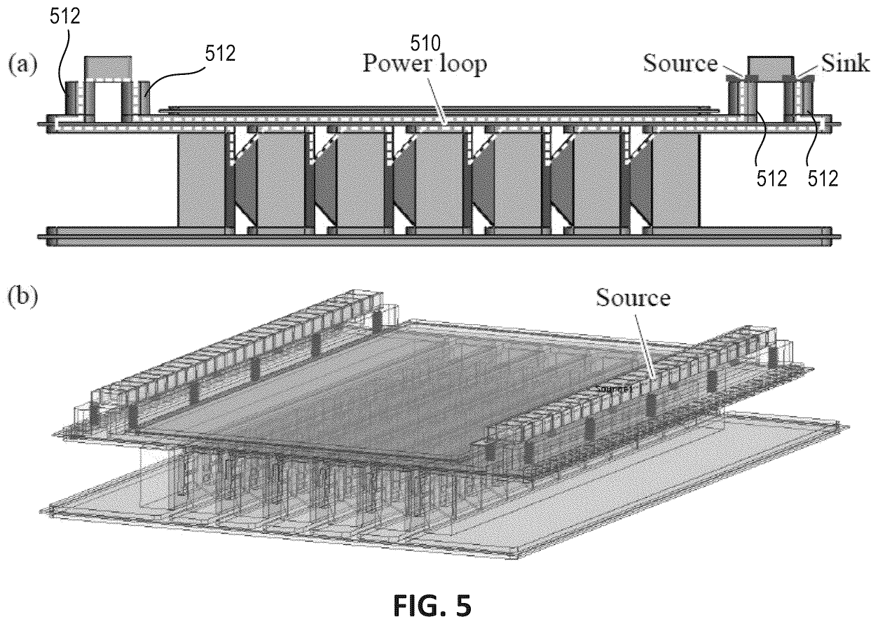

FIG. 5 illustrates a cross-section view of the half-bridge module, in accordance with one or more embodiments of the present disclosure. As shown in FIG. 5, the commutation power loop 510 is composed of the switch bars, AMB-2 copper plates, as well as external MLCC capacitors and their mounting bars 512. This loop 510 tightly encloses the narrow space occupied by the AMB-2 ceramic layer (e.g., 0.32 mm thick silicon nitride (Si₃N₄)) and the minimal gaps between switch bars and between capacitor mounting bars. As a result, the power-loop inductance remains exceptionally low, even with the decoupling capacitors mounted externally to the module. In the ANSYS Q3D simulation, a pair of source and sink are assigned to the top surfaces of the right-side capacitor mounting bars. The right-side MLCC capacitors are assigned as non-model elements, while the left-side capacitors are assigned as copper conductors. Under these settings, the simulated Ls=3.7 nH. Furthermore, this module can be integrated as a submodule within a larger package, potentially reducing Ls even further by parallel.

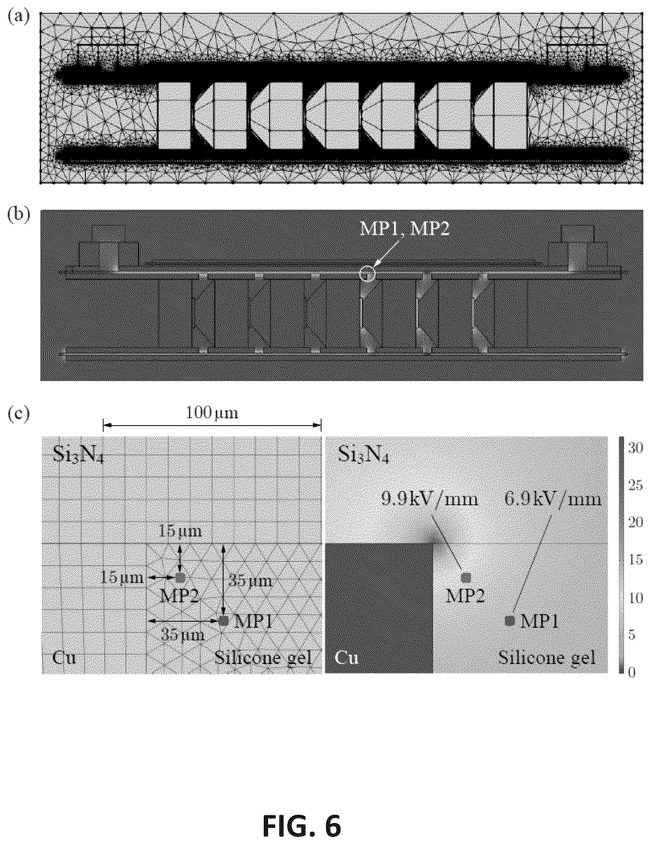

Using the voltage potential settings shown in FIG. 4, the E-field strength within the package was simulated using the COMSOL AC/DC Module. FIG. 6 shows E-field results, in accordance with one or more embodiments of the present disclosure. Specifically, (a) COMSOL mesh is set with an upper mesh size limit of 10 μm applied to critical components. E-field distribution of the module is shown in (b). Triple point mesh and E-field are illustrated in (c). The half-bridge module shown in FIG. 3A adopts the following configuration. For AMB-1 and AMB-2, the copper layer thickness is 0.8 mm and the Si₃N₄ layer thickness is 0.32 mm. For AMB-3, the copper layer thickness is 0.3 mm and the Si₃N₄ layer thickness is 0.25 mm. Material parameters are as follows. Electrical conductivity: Si₃N₄, 0 S/m; copper, 5.96×10⁷ S/m; silicone gel, 1.0×10⁻¹³ S/m. Relative permittivity: Si₃N₄, 9.7; copper, 1; silicone gel, 2.7. The E-field at the triple point is 36.5 kV/mm, at MP1 is 6.9 kV/mm, and at MP2 is 9.9 kV/mm.

The E-field magnitude was found to be sensitive to the mesh size, increasing as the mesh size decreased. Simulations with upper mesh limits of 5 μm, 10 μm, and 25 μm revealed significant variation in the E-field near the critical triple point, with differences ranging from 30% to 70%. However, beyond a distance of 20 μm from the edge, the E-field variation reduced to less than 1%. To mitigate the influence of mesh dependence, the E-field measurement point (MP1) was taken at a distance of 50 μm from the critical edge. In this simulation, the 50 μm diagonal distance was made by setting the horizontal and vertical distances to 35 μm. E-field at horizontal and vertical distances of 15 μm (MP2) is also measured for comparison.

As shown (a) and (c) of FIG. 6, specific meshing was implemented on the module, with an upper mesh size limit of 10 μm applied to critical components, including the triple-point ceramic, silicone gel, and copper substrate. Following the mesh size definitions, a free triangular mesh was applied to the encapsulation material, while a mapped mesh was used for the copper and ceramic components. For the remaining components, a combination of mapped and triangular meshing was employed, with normal and extra coarse mesh sizes.

The simulation results in (b) of FIG. 6 revealed that the E-field strength peaks at the triple point, reaching 36.5 kV/mm, while the value was 6.9 kV/mm at MP1 and 9.9 kV/mm at MP2 (shown in (c) of FIG. 6). This may guarantee PD-free performance. However, further encapsulation and PD testing need to be conducted for validation.

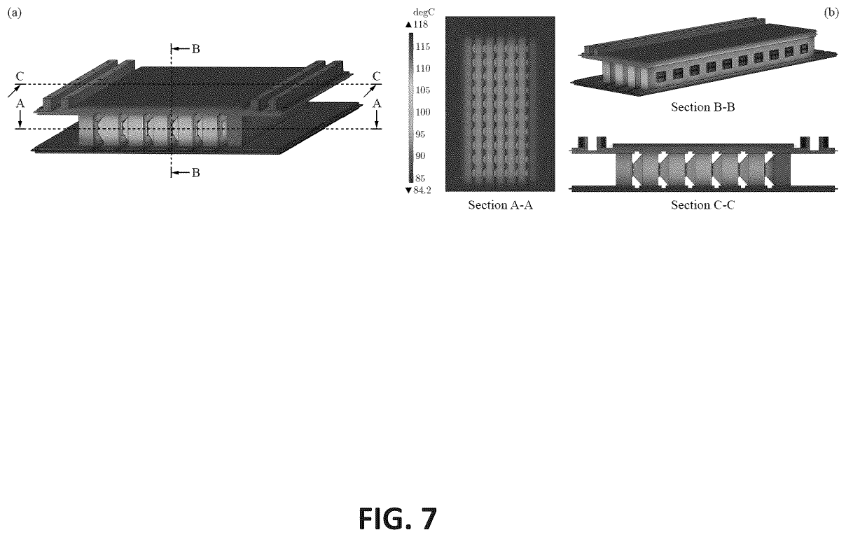

FIG. 7 illustrates thermal simulations, in accordance with one or more embodiments of the present disclosure.

The DOC design has two main goals: (1) to ensure the SiC die junction temperature Tⱼ<150° C. (with a 25° C. margin to 175° C.) and (2) to keep the substrate cooling interface temperature T_{c}<85° C., specifically, the bottom copper plate of AMB-1 and the top copper plate of AMB-3. Pin-fin baseplate water cooling is presumed, operating with a typical water volume flow rate of 3LPM-24LPM (or 0.05 L/s−0.4 L/s).

Thermal simulations in COMSOL were conducted in two steps to verify the design goals. In the first step, the cooling interface temperatures were fixed at T_{c,fixed}=85° C., with a device power loss of 125 W per die, amounting to a total of 7.5 kW for the 60 dies in the half-bridge module, as shown in FIG. 7. The result indicates that T_{j,max,fixed}=118° C., meeting the target requirements. The calculated junction-to-case thermal resistance is R_{th,j-c}=4.4 K/kW, with a per-die thermal resistance of R_{th,j-c,die}=0.264 K/W. This represents a 40% reduction compared to typical discrete devices (0.45 K/W) and falls within the range of dual-sided cooling performance reported in the literature. Although the cooling interface temperature is not uniform in practice, this verification provides a reasonable estimate of the DOC's thermal performance.

In the second step, a thermal simulation coupled with computational fluid dynamics (CFD) analysis is performed to verify that the pin-fin baseplate water cooling design maintains T_{c}<85° C. The pin-fin baseplates used in this study are based on the Wieland MDT, a non-subtractive method for fabricating pin-fin structures. The top and bottom pin-fin arrays have effective areas of A_{eff,top}=0.0174 m² and A_{eff,bot}=0.0264 m², respectively. Using the equation Rₜₕ=1/(A_{eff}·h) and an estimated convective heat transfer coefficient h=8.6 kW/m²·K at a 6 LPM flow rate, the cooler thermal resistances are calculated as R_{th,c,top}=6.7 K/kW and R_{th,c,bot}=4.4 K/kW, respectively.

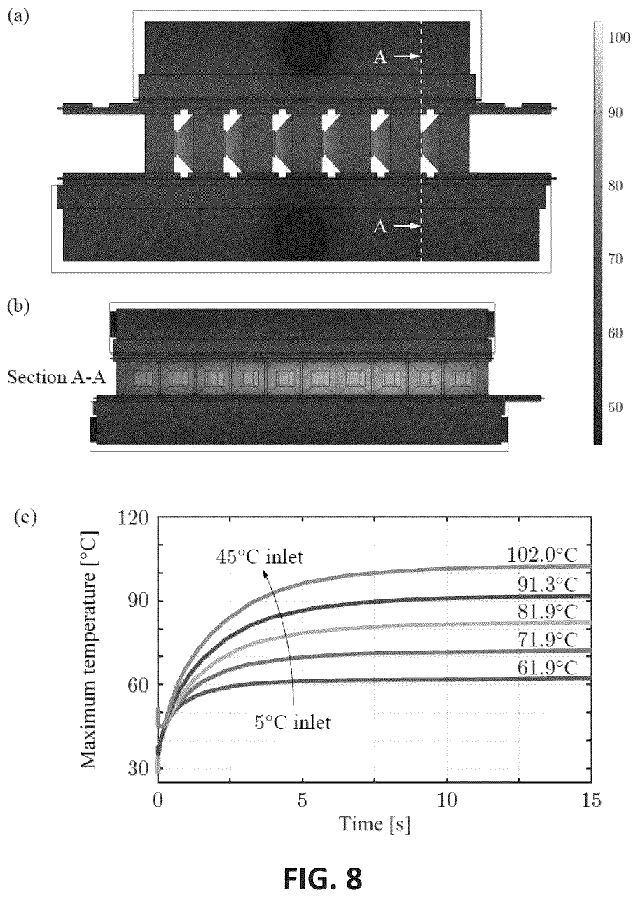

FIG. 8 illustrates thermal simulation results, in accordance with one or more embodiments of the present disclosure. Specifically (a) Simulated module temperature distribution with water cooling at a 45° C. inlet temperature and a flow rate of 6 LPM, measured at t=15 s. (b) Section A-A view to show the die temperatures. (c) Transient maximum temperature curves when various inlet water temperatures are applied: 5° C., 15° C., 25° C., 35° C., and 45° C.

FIG. 8 in (a) and (b) illustrates the steady-state (t=15 s) temperature distribution of the module with an inlet water temperature of 45° C., simulated using the COMSOL CFD Module and Heat Transfer Module. The average substrate cooling interface temperature is T_{c,cfd}=66.9° C., and the maximum junction temperature is T_{j,max,cfd}=102.0° C. FIG. 8 in (c) shows the time-domain transient maximum temperature curves when 5° C.-45° C. inlet water temperatures are applied, where the steady-state temperatures are linear but the time constants increase slightly.

Note that all performed DOC thermal simulations do not include bonding material layers, so the actual junction and substrate temperatures are expected moderately higher than the simulation results. Also, no thermal interface material is used.

It is noted that the techniques described herein may be embodied in executable instructions stored in a computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic format. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

The arrangement of components illustrated in the attached Figures are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. Various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

What is claimed is:

1. A semiconductor power module, comprising:
a first substrate;
a second substrate; and
a plurality of switch bars stacked and laterally positioned between the first substrate and the second substrate,
wherein each switch bar of the plurality of switch bars comprises:
a plurality of dies disposed in parallel, each die of the plurality of dies comprising a switch device with a source, a drain, and a gate;
a gate driver printed circuit board (PCB) connected to the gates of the switch devices in the plurality of dies; and
interconnects configured to connect the sources and drains of the switch devices in the plurality of dies, and
wherein the switch devices of the same switch bar are electrically connected in parallel and respective switch devices of different switch bars are electrically connected in series.

2. The semiconductor power module of claim 1, wherein the plurality of dies in the plurality of switch bars are positioned on a first surface of the respective switch bars, and the first surface of each respective switch bar is perpendicular to a surface of the first substrate and a surface of the second substrate.

3. The semiconductor power module of claim 2, wherein the gate driver PCB is connected to the first surface of the respective switch bar.

4. The semiconductor power module of claim 2, wherein a second surface of each switch bar of the plurality of switch bars comprises a plurality of pyramid extrusions corresponding to the plurality of dies on the respective switch bar, wherein the second surface of the respective switch bar faces opposite to the first surface of the respective switch bar.

5. The semiconductor power module of claim 1, further comprising:
a heatsink connected to the first substrate; and
one or more third substrates connected to the second substrate.

6. The semiconductor power module of claim 5, wherein the one or more third substrates correspond to separate heatsink voltage potentials.

7. The semiconductor power module of claim 5, further comprising:
a plurality of decoupling capacitors, wherein the plurality of decoupling capacitors is connected to the second substrate and positioned between adjacent third substrates of the one or more third substrates.

8. The semiconductor power module of claim 1, wherein the first and second substrates are active metal brazed substrates.

9. The semiconductor power module of claim 1, wherein the plurality of switch devices are metal-oxide-semiconductor field-effect transistors (MOSFETs) or junction field-effect transistors (JFETs).

10. The semiconductor power module of claim 1, wherein each switch bar of the plurality of switch bars comprises a copper bar.

11. The semiconductor power module, comprising:
a plurality of submodules; and
a heatsink connected to first substrates of the plurality of submodules,
wherein each submodule of the plurality of submodules comprises:
a first substrate;
a second substrate; and
a plurality of switch bars stacked and laterally positioned between the first substrate and the second substrate,
wherein each switch bar of the plurality of switch bars comprises:
a plurality of dies disposed in parallel, each die of the plurality of dies comprising a switch device with a source, a drain, and a gate;
a gate driver printed circuit board (PCB) connected to the gates of the switch devices in the plurality of dies; and
interconnects configured to connect the sources and drains of the switch devices in the plurality of dies, and
wherein the switch devices of the same switch bar are electrically connected in parallel and respective switch devices of different switch bars are electrically connected in series.

12. The semiconductor power module of claim 11, wherein the plurality of submodules is oriented in different directions.

13. The semiconductor power module of claim 11, wherein the plurality of dies in the plurality of switch bars are positioned on a first surface of the respective switch bars, and the first surface of each respective switch bar is perpendicular to a surface of the first substrate and a surface of the second substrate.

14. The semiconductor power module of claim 13, wherein the gate driver PCB is connected to the first surface of the respective switch bar.

15. The semiconductor power module of claim 13, wherein a second surface of each switch bar of the plurality of switch bars comprises a plurality of pyramid extrusions corresponding to the plurality of dies on the respective switch bar, wherein the second surface of the respective switch bar faces opposite to the first surface of the respective switch bar.

16. The semiconductor power module of claim 11, further comprising:
one or more third substrates connected to the second substrates of the plurality of submodules.

17. The semiconductor power module of claim 16, wherein the one or more third substrates correspond to separate heatsink voltage potentials.

18. The semiconductor power module of claim 17, further comprising:
a plurality of decoupling capacitors, wherein the plurality of decoupling capacitors is connected to the second substrates of the plurality of submodules and positioned between adjacent third substrates of the one or more third substrates.

19. The semiconductor power module of claim 1, wherein the plurality of switch devices are metal-oxide-semiconductor field-effect transistors (MOSFETs) or junction field-effect transistors (JFETs).

20. A method for packaging a semiconductor power module, comprising:
fabricating a plurality of switch bars, wherein each switch bar of the plurality of switch bars comprises:
a plurality of dies disposed in parallel, each die of the plurality of dies comprising a switch device with a source, a drain, and a gate;
a gate driver printed circuit board (PCB) connected to the gates of the switch devices in the plurality of dies; and
interconnects configured to connect the sources and drains of the switch devices in the plurality of dies;
stacking the plurality of switch bars; and
laterally positioning the stacked switch bars between a first substrate and a second substrate.
